(19) United States
(12) Patent Application Publication
(10) Pub. No.: US 2015/0084012 A1
(43) Pub. Date: Mar. 26, 2015

(54) ORGANIC LIGHT EMITTING DISPLAY APPARATUS AND METHOD OF MANUFACTURING THE SAME

(71) Applicant: SAMSUNG DISPLAY CO., LTD., Yongin-City (KR)

(72) Inventors: Jin-Kwang KIM, Yongin-City (KR); Jae-Hyun KIM, Yongin-City (KR); Hang-Ki RO, Yongin-City (KR); Chang-Woo SHIM, Yongin-City (KR); Suk-Won JUNG, Yongin-City (KR); Sun-Taek JEONG, Yongin-City (KR); Myung-Soo HUH, Yongin-City (KR)

(73) Assignee: SAMSUNG DISPLAY CO., LTD., Yongin-City (KR)

(21) Appl. No.: 14/291,045

(22) Filed: May 30, 2014

(30) Foreign Application Priority Data
Sep. 26, 2013 (KR) 10-2013-0114691

(51) Int. Cl. H01L 51/52; H01L 51/56

(52) U.S. Cl. CPC H01L 51/5256; H01L 51/56
USPC 257/40; 438/26

(57) ABSTRACT

An organic light emitting display apparatus includes a substrate, a display unit on the substrate, a dispersion layer on the display unit, and a thin film encapsulation layer sealing the display unit and the dispersion layer. The dispersion layer has a diffusion coefficient in a horizontal direction that is greater than a diffusion coefficient in a vertical direction.

### CROSS-REFERENCE TO RELATED APPLICATION

Korean Patent Application No. 10-2013-0114691, filed on Sep. 26, 2013, in the Korean Intellectual Property Office, and entitled: “Organic Light Emitting Display Apparatus and Method Of Manufacturing The Same,” is incorporated by reference herein in its entirety.

### BACKGROUND

1. Field

Embodiments relate to an organic light emitting display apparatus and a method of manufacturing the same.

2. Description of the Related Art

An organic light emitting display apparatus is a self-emission type display apparatus including an organic light emitting device (OLED). The organic light emitting device includes a hole injection electrode, an electron injection electrode, and an organic emission layer disposed between the hole injection electrode and the electron injection electrode. Excitons that are generated by combining holes injected from the hole injection electrode and electrons injected from the electron injection electrode in the organic emission layer enter ground states from excited states to emit light.

The organic light emitting display apparatus is a self-emission type display apparatus that does not need an additional light source, the organic light emitting display apparatus may be driven with a low voltage and may be formed thin and light. In addition, the organic light emitting display apparatus is considered as a next generation display apparatus owing to characteristics thereof such as wide viewing angles, high contrast, and fast response speeds.

### SUMMARY

Embodiments are directed to an organic light emitting display apparatus including a substrate, a display unit on the substrate, a dispersion layer on the display unit, and a thin film encapsulation layer sealing the display unit and the dispersion layer. The dispersion layer has a diffusion coefficient in a horizontal direction that is greater than a diffusion coefficient in a vertical direction.

The dispersion layer may include a first layer and a second layer on the first layer. A diffusion coefficient of the first layer may be greater than a diffusion coefficient of the second layer.

The first layer may include an organic material. The second layer may include at least one of SiO₂, SiNx, and Al₂O₃.

The second layer may have a thickness of a single atomic layer.

The first layer and the second layer may be alternately and repeatedly stacked.

The second layer may include a plurality of pin holes that are evenly distributed.

The second layer may have a thickness of about 1.5 nm to about 7.5 nm.

The first layer and the second layer may be alternately and repeatedly stacked.

The thin film encapsulation layer may include at least a pair of an inorganic layer and an organic layer.

Embodiments are also directed to an organic light emitting display apparatus including a substrate, a display unit on the substrate, a dispersion layer on the display unit, and a thin film encapsulation layer sealing the display unit and the dispersion layer. The dispersion layer includes a first layer and a second layer on the first layer, and diffusion coefficients of the first layer and the second layer are different.

The diffusion coefficient of the first layer may be greater than the diffusion coefficient of the second layer. The first layer may include an organic material and the second layer includes an inorganic material.

The second layer may include at least one of SiO₂, SiNx, and Al₂O₃.

The second layer may have a thickness of a single atomic layer.

A plurality of the first layers and a plurality of the second layers may be stacked alternately with each other.

The second layer may include a plurality of pin holes that are evenly distributed.

The thin film encapsulation layer may include at least a pair of an inorganic layer and an organic layer.

Embodiments are also directed to a method of manufacturing an organic light emitting display apparatus including forming a display unit on a substrate, forming a dispersion layer on the display unit, and forming a thin film encapsulation layer on the dispersion layer to seal the display unit and the dispersion layer. The dispersion layer has a diffusion coefficient in a horizontal direction that is greater than a diffusion coefficient in a vertical direction, and includes a first layer formed of an organic material and a second layer formed of an inorganic material on the first layer and having porosity.

The second layer may be formed by depositing at least one of SiO₂, SiNx, and Al₂O₃ to a thickness of a single atomic layer.

The second layer may be formed through nano-crystallization.

The second layer may include a plurality of pin holes that are evenly distributed.

### BRIEF DESCRIPTION OF THE DRAWINGS

Features will become apparent to those of skill in the art by describing in detail exemplary embodiments with reference to the attached drawings in which:

FIG. 1 illustrates a schematic cross-sectional view of an organic light emitting display apparatus according to an embodiment;

FIG. 2 illustrates a schematic cross-sectional view of a display unit in the organic light emitting display apparatus of FIG. 1;

FIG. 3 illustrates a schematic cross-sectional view of a dispersion layer in the organic light emitting display apparatus of FIG. 1;

FIG. 4 illustrates a schematic cross-sectional view showing another example of the dispersion layer in the organic light emitting display apparatus of FIG. 1; and

FIG. 5 illustrates a diagram showing effects according to whether the dispersion layer is formed in the organic light emitting display apparatus of FIG. 1.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

It will be understood that although the terms “first”, “second”, etc. may be used herein to describe various components, these components should not be limited by these terms. These components are only used to distinguish one component from another.

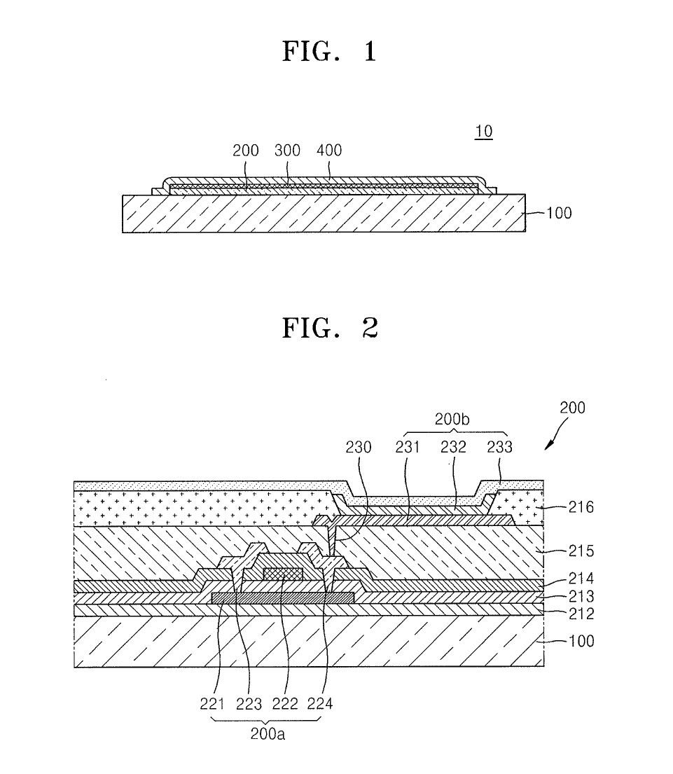

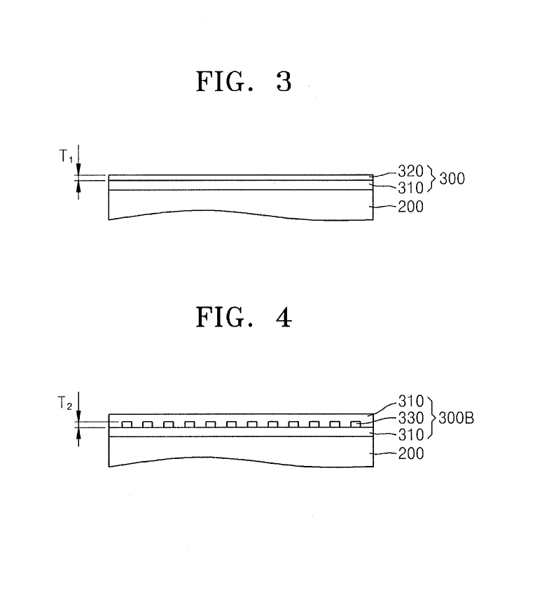

FIG. 1 illustrates a schematic cross-sectional view of an organic light emitting display apparatus 10 according to an embodiment, FIG. 2 illustrates a schematic cross-sectional view of a display unit 200 in the organic light emitting display apparatus 10 of FIG. 1, and FIG. 3 illustrates a schematic cross-sectional view of a dispersion layer 300 in the organic light emitting display apparatus 10 of FIG. 1.

Referring to FIGS. 1 to 3, the organic light emitting display apparatus 10 according to an embodiment may include a substrate 100, the display unit 200 formed on the substrate 100, the dispersion layer 300 formed on the display unit 200, and a thin film encapsulation layer 400 for sealing the display unit 200 and the dispersion layer 300.

The substrate 100 may be formed of a transparent glass material mainly containing SiO₂. In other implementations, the substrate 100 may be formed of a transparent plastic material. The plastic material forming the substrate 100 may be an insulating organic material, for example, an organic material selected from the group of polyethersulfone (PES), polyacrylate (PAR), polyetherimide (PEI), polyethylene naphthalate (PEN), polyethylene terephthalate (PET), polyphenylene sulfide (PPS), polyallylate, polyimide, polycarbonate (PC), cellulose tri-acetate (TAC), cellulose acetate propionate (CAP).

If the organic light emitting display apparatus 10 is a bottom emission type, in which images are displayed toward the substrate 100, the substrate 100 may be formed by using a transparent material. However, if the organic light emitting display apparatus 10 is a top emission type, in which images are displayed away from the substrate 100, the substrate 100 need not be formed of a transparent material. For example, the substrate 100 may be formed of metal. For example, the substrate 100 may include one or more selected from the group consisting of carbon, iron, chromium, manganese, nickel, titanium, molybdenum, stainless steel (SUS), an Invar alloy, an Inconel alloy, and a Kovar alloy.

The display unit 200 may be formed on the substrate 100, and may include a thin film transistor (TFT) 200a and an organic light emitting device (OLED) 200b. The display unit 200 will be described in detail with reference to FIG. 2.

A buffer layer 212 may be formed on the substrate 100. The buffer layer 212 may prevent impurity atoms from infiltrating into the substrate 100 and may provide a flat surface on an upper portion of the substrate 100. The buffer layer 212 may be formed of various materials that perform the above functions. For example, the buffer layer 212 may include an inorganic material such as silicon oxide, silicon nitride, silicon oxynitride, aluminum oxide, aluminum nitride, titanium oxide, or titanium nitride, or an organic material such as polyimide, polyester, or acryl, and may be formed as a stacked body including a plurality of layers formed of the above examples.

An active layer 221 may be formed on the buffer layer 212. The active layer 221 may be formed of an inorganic semiconductor such as silicon, or of an organic semiconductor. The active layer 221 may include a source region, a drain region, and a channel region between the source and drain regions. For example, if the active layer 221 is formed of amorphous silicon, an amorphous silicon layer may be formed on an entire surface of the substrate 100 and crystallized to form a polycrystalline silicon layer. In addition, the polycrystalline silicon layer may be patterned, and the source and drain regions may be doped with impurities to form the active layer 221 including the source region, the drain region, and the channel region between the source and drain regions.

A gate insulating layer 213 may be formed on the active layer 221. The gate insulating layer 213 is formed to insulate a gate electrode 222 from the active layer 221. The gate insulating layer 213 may be formed of an inorganic material such as SiNx or SiO₂.

The gate electrode 222 may be formed on a predetermined region of the gate insulating layer 213. The gate electrode 222 may be connected to a gate line applying turn on/off signals to a TFT.

The gate electrode 222 may be formed of various materials. For example, the gate electrode 222 may include Au, Ag, Cu, Ni, Pt, Pd, Al, or Mo, or an alloy such as Al:Nd alloy or Mo:W alloy.

An interlayer insulating layer 214 may be formed on the gate electrode 222 to insulate between the gate electrode 222 and a source electrode 223 and a drain electrode 224. The interlayer insulating layer 214 may be formed of an inorganic material such as SiNx and SiO₂.

The source electrode 223 and the drain electrode 224 may be formed on the interlayer insulating layer 214. The interlayer insulating layer 214 and the gate insulating layer 213 may expose the source region and the drain region. The source electrode 223 and the drain electrode 224 may contact the exposed source and drain regions of the active layer 221.

In addition, FIG. 2 shows a top gate type TFT including the active layer 221, the gate electrode 222, the source electrode 223, and the drain electrode 224 sequentially. In other implementations, the gate electrode 222 may be disposed under the active layer 221.

The TFT 200a may be electrically connected to the OLED 200b to drive the OLED 200b, and may be protected by a planarization layer 215.

The planarization layer 215 may include an inorganic insulating layer and/or an organic insulating layer. The inorganic insulating layer may include SiO₂, SiNx, SiON, Al₂O₃, TiO₂, Ta₂O₅, HfO₂, ZrO₂, BST, or PZT. The organic insulating layer may include polymers such as poly(methyl methacrylate) (PMMA) or polystyrene (PS), a polymer derivative including a phenol group, an acryl-based polymer, an imide-based polymer, an aryl ether-based polymer, an amide-based polymer, a fluoride-based polymer, a p-xylene-based polymer, a vinyl alcohol-based polymer, or blends thereof. The planarization layer 215 may be formed as a composite stacked layer of the inorganic insulating layer and the organic insulating layer.

The OLED 200b may include a pixel electrode 231, an intermediate layer 232, and an opposite electrode 233.

The pixel electrode 231 may be formed on the planarization layer 215. The pixel electrode 231 may be electrically connected to the drain electrode 224 via a contact hole 230 formed in the planarization layer 215.

The pixel electrode 231 may be a reflective electrode. The pixel electrode 231 may include a reflective layer formed of Ag, Mg, Al, Pt, Pd, Au, Ni, Nd, Ir, Cr, or a compound thereof, and a transparent or a semi-transparent electrode layer formed on the reflective layer. The transparent or semi-transparent electrode layer may include at least one selected from the group of indium tin oxide (ITO), indium zinc oxide (IZO), zinc oxide (ZnO), indium oxide (In₂O₃), indium gallium oxide (IGO), and aluminum zinc oxide (AZO).

The opposite electrode 233 facing the pixel electrode 231 may be a transparent or a semi-transparent electrode. The opposite electrode 233 may be formed as a metal thin film having a small work function and may include Li, Ca, LiF/Ca, LiF/Al, Al, Ag, Mg, or a compound thereof. Also, an auxiliary electrode layer or a bus electrode may be formed on the metal thin film. The auxiliary electrode layer or a bus electrode may be formed of a transparent electrode forming material such as ITO, IZO, ZnO, or In₂O₃.

The opposite electrode 233 may transmit light emitted from an organic emission layer included in the intermediate layer 232. The light emitted from the organic emission layer may be emitted toward the opposite electrode 233 directly or after being reflected by the pixel electrode 231 formed as the reflective electrode.

In other implementations, the organic light emitting display apparatus 10 may be a bottom emission type, in which light emitted from the organic emission layer is discharged toward the substrate 100. In this case, the pixel electrode 231 may be formed as a transparent or semi-transparent electrode, and the opposite electrode 233 may be formed as a reflective electrode. In other implementations, the organic light emitting display apparatus 10 according to the present embodiment may be a dual-emission type emitting light to front and rear surfaces.

A pixel defining layer 216 may be formed of an insulating material on the pixel electrode 231. The pixel defining layer 216 may be formed of at least one organic insulating material selected from the group of polyimide, polyamide, an acryl resin, benzocyclobutene, and a phenol resin by a spin coating method. The pixel defining layer 216 may expose a predetermined region of the pixel electrode 231. The intermediate layer 232, including the organic emission layer, may be located on the exposed region.

The organic emission layer included in the intermediate layer 232 may be formed of a lower molecular organic material or a high molecular organic material. The intermediate layer 232 may selectively include additional functional layers such as a hole transport layer (HTL), a hole injection layer (HIL), an electron transport layer (ETL), or an electron injection layer (EIL), in addition to the organic emission layer.

The dispersion layer 300 may be formed on the display unit 200. Even if external moisture were to infiltrate into the thin film encapsulation layer 400 via pin holes formed in the thin film encapsulation layer 400, the dispersion layer 300 may disperse the moisture widely, thereby preventing dark spots from being generated in the organic light emitting display apparatus 10.

The dispersion layer 300 may be formed of a material having diffusion coefficients that are different in a horizontal direction and a vertical direction. The dispersion layer 300 may be formed of a material having a diffusion coefficient in the horizontal direction that is greater than that in the vertical direction. When the diffusion coefficient of the dispersion layer 300 in the horizontal direction is greater than that in the vertical direction, the dispersion layer 300 may widely disperse moisture that infiltrates through the pin holes formed in the thin film encapsulation layer 400 in a horizontal direction, thereby preventing the moisture from concentrating on any specific region of the OLED 200b. Therefore, specific spots of the opposite electrode 233 may avoid being oxidized by the infiltrated moisture, and the occurrence of dark spots may be prevented.

Also, as shown in FIG. 3, the dispersion layer 300 may be formed by stacking a first layer 310 and a second layer 320 having different diffusion coefficients so that the diffusion coefficient of the dispersion layer 300 in the horizontal direction may be greater than that in the vertical direction.

The first layer 310 may have a diffusion coefficient that is greater than that of the second layer 320. For example, the first layer 310 may be formed of an organic material, and the second layer 320 may be formed of an inorganic material. The organic material may be, for example, polyethylene terephthalate, polyimide, polycarbonate, epoxy, polyethylene, or polyacrylate, and the inorganic material may be, for example, at least one of SiO₂, SiNx, and Al₂O₃.

The second layer 320 having the diffusion coefficient that is less than that of the first layer 310 may reduce a diffusion speed of moisture in the vertical direction, and at the same time, may disperse the moisture widely in the horizontal direction. In particular, the second layer 320 may be porous throughout an entire area. The moisture may be widely dispersed in the horizontal direction to pass through the second layer 320.

In order for the second layer 320 to have uniform porosity, the second layer 320 may be very small in thickness T₁. For example, the second layer 320 may have a thickness of a single atomic layer. In addition, the second layer 320 may be formed by using an atomic layer deposition (ALD) method.

In addition, the second layer 320 may be formed of a material that is the same as a material forming an inorganic layer included in the thin film encapsulation layer 400 that will be described below If the thickness T₁ of the second layer 320 is the thickness of a single atomic layer, particulates of the second layer 320 may have porous morphologies that are independently grown. The second layer 320 may have uniform porosity throughout an entire area.

On the other hand, if the second layer 320 were to have a thickness T₁ that is greater than the thickness of single atomic layer, the second layer 320 could include concentrated particulates, and the second layer 320 could have a property of a barrier layer preventing moisture infiltration. In this case, stress applied to the second layer 320 could be increased, thereby generating inconsistent cracks. The moisture could be concentrated in the cracks, rather than being dispersed by the cracks.

As illustrated in FIG. 3, the first layer 310 may be located on the display unit 200. In other implementations, the second layer 320 may be formed on the display unit 200 and the first layer 310 may be formed on the second layer 320. The first layer 310 and the second layer 320 may be repeatedly stacked on each other.

The first layer 310 may be formed of an organic material, and the second layer 320 may be formed of an inorganic material. In other implementations, if the diffusion coefficients of the first layer 310 and the second layer 320 are different, both the first and second layers 310 and 320 may be formed of an organic material or an inorganic material.

Referring back to FIG. 1, the thin film encapsulation layer 400 for sealing the display unit 200 and the dispersion layer 300 may be formed on the dispersion layer 300. The thin film encapsulation layer 400 may extend to cover side surfaces of the display unit 200 and the dispersion layer 300, as well as the upper surface of the thin film encapsulation layer 300, so as to contact a part of the substrate 100. Penetration of external oxygen and moisture may be prevented.

The thin film encapsulation layer 400 may include a plurality of inorganic layers, or organic layers and inorganic layers.

The organic layer of the thin film encapsulation layer 400 may be formed of polymer and may be a single layer or a layer stack formed of any one of polyethylene terephthalate, polyimide, polycarbonate, epoxy, polyethylene, and polyacrylate. The organic layer may be formed of polyacrylate, and, for example, may include a polymerized monomer composition including a diacrylate-based monomer and a triacrylate-based monomer. The monomer composition may further include a monoacrylate-based monomer. The monomer composition may further include a photoinitiator such as trimethyl benzoyl diphenyl phosphine oxide (TPO), as an example.

The inorganic layer of the thin film encapsulation layer 400 may be a single layer or a layer stack including a metal oxide or a metal nitride. For example, the inorganic layer may include any one of SiNx, Al₂O₃, SiO₂, and TiO₂.

The thin film encapsulation layer 400 may include at least one sandwich structure in which at least one organic layer is inserted between at least two inorganic layers. In another implementation, the thin film encapsulation layer 400 may include at least one sandwich structure in which at least one inorganic layer is inserted between at least two organic layers. In another implementation, the thin film encapsulation layer 400 may include a sandwich structure in which at least one organic layer is inserted between at least two inorganic layers and a sandwich structure in which at least one inorganic layer is inserted between at least two organic layers. The top layer of the thin film encapsulation layer 400 that is exposed to the outside may be formed of an inorganic layer, in order to prevent the intrusion of moisture into the OLED.

The thin film encapsulation layer 400 may include a first inorganic layer, a first organic layer, and a second inorganic layer that are sequentially formed from the top portion of the OLED. In another implementation, the thin film encapsulation layer 400 may include a first inorganic layer, a first organic layer, a second inorganic layer, a second organic layer, and a third inorganic layer that are sequentially formed from the top portion of the OLED. In another implementation, the thin film encapsulation layer 400 may include a first inorganic layer, a first organic layer, a second inorganic layer, a second organic layer, a third inorganic layer, a third organic layer, and a fourth inorganic layer that are sequentially formed from the top portion of the OLED.

The first organic layer may be smaller than the second inorganic layer, and the second organic layer may be smaller than the third inorganic layer. In another implementation, the first organic layer may be completely covered by the second inorganic layer, and the second organic layer may be completely covered by the third inorganic layer.

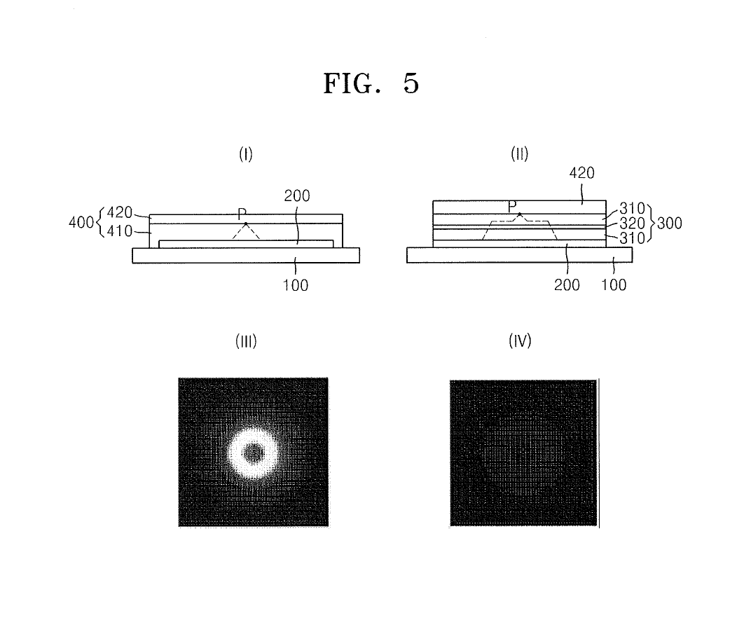

FIG. 4 illustrates a schematic cross-sectional view showing another example of a dispersion layer 300B included in the organic light emitting display apparatus 10 of FIG. 1.

The dispersion layer 300B in FIG. 4 may be formed on the display unit 200, and may include the first layer 310 and the second layer 330 having different diffusion coefficients so as to disperse moisture widely and prevent dark spots from being generated in the display unit 200.

The first layer 310 may be formed of an organic material such as polyethylene terephthalate, polyimide, polycarbonate, epoxy, polyethylene, or polyacrylate.

The second layer 330 may have a diffusion coefficient that is less than that of the first layer 310, and may be formed of at least one inorganic material of SiO₂, SiNx, and Al₂O₃.

The second layer 330 may have defects that are evenly distributed, and thus, the second layer 330 may be porous. For example, the defects may be pin holes. Pin holes that are evenly distributed may disperse moisture in the horizontal direction. The pin hole may be much smaller than a sub-pixel of the display unit 200.

For example, the defects such as the pin holes may be formed by patterning the second layer 330 using a metal patterning method.

The second layer 330 may be formed to have a thickness T₂ of about 1.5 nm to about 7.5 nm. If the thickness T₂ of the second layer 330 is greater than 7.5 nm, stress applied to the second layer 330 may increase, and thus, it is possible that cracks may be generated. Thus, it may be difficult to form the defects such as pin holes that are evenly distributed. On the other hand, if the thickness T₂ of the second layer 330 is less than 1.5 nm, the second layer 330 may be too thin to form the defects such as pin holes by using the patterning method.

In another example, the second layer 330 may be formed through nano-crystallization. When SiO₂ of an amorphous state is applied and crystallized to form the second layer 330, pin holes each having a size of several Å may be evenly distributed.

In addition, in FIG. 4, the second layer 330 formed on the first layer 310 may be covered by another first layer 310. For example, the first layer 310 and the second layer 330 may be stacked alternately and repeatedly. In other implementations, the second layer 330 may be formed on the display unit 200.

FIG. 5 illustrates a diagram showing effects when an organic light-emitting display apparatus, which is otherwise the same as the organic light-emitting display apparatus 10 of FIG. 1, does not include a dispersion layer and effects when the organic light emitting display apparatus 10 does include the dispersion layer 10.

In FIG. 5, (I) denotes a case where the thin film encapsulation layer 400 directly seals the display unit 200, without a dispersion layer, and (II) denotes a case where the dispersion layer 300 is formed on the display unit 200 and the thin film encapsulation layer 400 seals the display unit 200 and the dispersion layer 300. In (I) and (II) of FIG. 5, a pin hole P is formed in an inorganic layer 420 of the thin film encapsulation layer 400, which is the closest to the display unit 200, and moisture is infiltrated through the pin hole P.

Referring to (I) of FIG. 5, a layer of the thin film encapsulation layer 400, which contacts the display unit 200, is an organic layer 410. The moisture introduced through the pin hole P formed in the inorganic layer 420 is diffused in a radial direction based on the pin hole P. Then, as shown in (III) of FIG. 5, the moisture is concentrated on the pin hole P, thereby generating a dark spot in the organic light emitting display apparatus 10.

However, (II) of FIG. 5 shows a case where the dispersion layer 300, including the first layer 310, the second layer 320, and the first layer 310, is formed on the display unit 200 so that the moisture introduced through the pin hole P formed in the thin film encapsulation layer 400 is widely dispersed. The second layer 320 has a diffusion coefficient that is less than that of the first layer 310 and has even porosity. Accordingly, moisture is widely diffused in the horizontal direction when passing through the second layer 320. Therefore, as shown in (IV) of FIG. 5, moisture is not concentrated on a particular region, and thus, the occurrence of the dark spot may be prevented, even when the moisture infiltrates through the pin hole P.

By way of summation and review, an OLED may be easily degraded due to external moisture or oxygen. Accordingly it is desirable to prevent the external moisture or oxygen from infiltrating into the OLED.

As described above, according to the one or more of the above embodiments, the infiltration of the external moisture or oxygen into the OLED may be prevented, or effects thereof may be minimized. Accordingly, defects such as dark spots on the organic light emitting display apparatus may be reduced.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope thereof as set forth in the following claims.

What is claimed is:

1. An organic light emitting display apparatus, comprising:
a substrate;
a display unit on the substrate;
a dispersion layer on the display unit; and
a thin film encapsulation layer sealing the display unit and the dispersion layer,
wherein the dispersion layer has a diffusion coefficient in a horizontal direction that is greater than a diffusion coefficient in a vertical direction.

2. The organic light emitting display apparatus as claimed in claim 1, wherein:
the dispersion layer includes a first layer and a second layer on the first layer, and
a diffusion coefficient of the first layer is greater than a diffusion coefficient of the second layer.

3. The organic light emitting display apparatus as claimed in claim 2, wherein:
the first layer includes an organic material, and
the second layer includes at least one of SiO₂, SiNx, and Al₂O₃.

4. The organic light emitting display apparatus as claimed in claim 3, wherein the second layer has a thickness of a single atomic layer.

5. The organic light emitting display apparatus as claimed in claim 4, wherein the first layer and the second layer are alternately and repeatedly stacked.

6. The organic light emitting display apparatus as claimed in claim 3, wherein the second layer includes a plurality of pin holes that are evenly distributed.

7. The organic light emitting display apparatus of claim 3, wherein the second layer has a thickness of about 1.5 nm to about 7.5 nm.

8. The organic light emitting display apparatus as claimed in claim 7, wherein the first layer and the second layer are alternately and repeatedly stacked.

9. The organic light emitting display apparatus as claimed in claim 1, wherein the thin film encapsulation layer includes at least a pair of an inorganic layer and an organic layer.

10. An organic light emitting display apparatus, comprising:
a substrate;
a display unit on the substrate;
a dispersion layer on the display unit; and
a thin film encapsulation layer sealing the display unit and the dispersion layer,
wherein the dispersion layer includes a first layer and a second layer on the first layer, and diffusion coefficients of the first layer and the second layer are different.

11. The organic light emitting display apparatus as claimed in claim 10, wherein:
the diffusion coefficient of the first layer is greater than the diffusion coefficient of the second layer, and
the first layer includes an organic material and the second layer includes an inorganic material.

12. The organic light emitting display apparatus as claimed in claim 11, wherein the second layer includes at least one of SiO₂, SiNx, and Al₂O₃.

13. The organic light emitting display apparatus as claimed in claim 12, wherein the second layer has a thickness of a single atomic layer.

14. The organic light emitting display apparatus as claimed in claim 13, wherein a plurality of the first layers and a plurality of the second layers are stacked alternately with each other.

15. The organic light emitting display apparatus as claimed in claim 12, wherein the second layer includes a plurality of pin holes that are evenly distributed.

16. The organic light emitting display apparatus as claimed in claim 10, wherein the thin film encapsulation layer includes at least a pair of an inorganic layer and an organic layer.

17. A method of manufacturing an organic light emitting display apparatus, the method comprising:
forming a display unit on a substrate;
forming a dispersion layer on the display unit; and
forming a thin film encapsulation layer on the dispersion layer to seal the display unit and the dispersion layer,
wherein the dispersion layer has a diffusion coefficient in a horizontal direction that is greater than a diffusion coefficient in a vertical direction, and includes a first layer formed of an organic material and a second layer formed of an inorganic material on the first layer and having porosity.

18. The method as claimed in claim 17, wherein the second layer is formed by depositing at least one of SiO₂, SiNx, and Al₂O₃ to a thickness of a single atomic layer.

19. The method as claimed in claim 17, wherein the second layer is formed through nano-crystallization.

20. The method as claimed in claim 19, wherein the second layer includes a plurality of pin holes that are evenly distributed.
